(19) United States
(12) Patent Application Publication
(10) Pub. No.: US 2008/0121182 A1
(43) Pub. Date: May 29, 2008

(54) APPARATUS OF SUPPLYING ORGANOMETALLIC COMPOUND

(75) Inventors: Toshimitsu Abe, Niiham-shi (JP); Naoyuki Ide, Niihama-shi (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY, LIMITED, Tokyo (JP)

(21) Appl. No.: 11/941,139

(22) Filed: Nov. 16, 2007

(30) Foreign Application Priority Data
Nov. 27, 2006 (JP) 2006-318305

(51) Int. Cl. C23C 16/18

(52) U.S. Cl. 118/726

(57) ABSTRACT

An apparatus of supplying an organometallic compound comprising a vessel into which a solid organometallic compound at room temperature is placed and a carrier gas to sublimate the organometallic compound is supported,
a supporter plate capable of maintaining an organometallic compound supported on an inert support in the lower part of the vessel with passing a carrier gas therethrough,
a carrier gas inlet in the upper part of the vessel, and a carrier gas outlet downward of the supporter plate of being the bottom part of the vessel are disposed, and wherein
the carrier gas is passed through the organometallic compound supported on the inert support loaded on the supporter plate from the above downward, is provided.

### BACKGROUND OF THE INVENTION

1. Field of the Invention

The present invention relates to an apparatus of supplying a solid organometallic compound. Specifically, the invention relates to an apparatus of supplying a solid organometallic compound that can further increases the amount of which the organometallic compound is supplied at room temperature at more stable concentration.

2. Description of the Related Art

In the epitaxial growth of compound semiconductors, organometallic compounds are used as raw materials. Organometallic compounds are particularly frequently used in a Metal Organic Chemical Vapor Deposition process (MOCVD process) excellent in mass productivity and controllability.

For Example, in high mobility electronic devices, high luminance optical devices, lasers for high capacity optical communication, lasers for high density recording, and the like, trimethyl indium which is in the solid state at its use temperature has been used in a large amount. In addition, when a luminous blue element is fabricated, biscyclopentadienyl magnesium or the like used as a p-type dopant for a gallium nitride is used.

An organometallic compound is placed into a vessel and the organometallic compound in contact with the carrier gas is sublimating into the carrier gas by flowing carrier gas and then is taken out of the vessel to be supplied to a phase growth apparatus or the like.

The vessel is usually a stainless steel cylinder and has various characteristics for the structure of the bottom, an inlet tube of a carrier gas and the like in order to improve heat efficiency, controllability of the concentration of an organometallic compound, an efficiency of the vaporized amount, and the like. Additionally, from the viewpoint of improved productivity, larger apparatuses have come to be employed.

In an organometallic compound in a liquid state at its use temperature such as trimethyl gallium or trimethyl aluminium, the organometallic compound is flowed by bubbling a carrier gas through the organometallic compound in the liquid state, readily causing the contact of a carrier gas with an organometallic compound, whereby the organometallic compound is taken out of the vessel along with a carrier gas (FIG. 1).

On the other hand, when a solid organometallic compound such as trimethyl indium is used, the contact of a carrier gas is not uniform and the consumption in the part is predominantly increased more than that in the other part. Subsequently, continuously the consumption of the part is increased to form a passage and, in places where the carrier gas does not flow in, the solid organometallic compound is not consumed but remains. Thus, a solid organometallic compound is not taken out at a stable concentration for a long period of time (FIG. 2).

For the efficient contact of the solid organometallic compound with the carrier gas, there are proposed a method of placing a solid organometallic compound supported on an inert support in a vessel and flowing the carrier gas downward from above the vessel (FIG. 3) (see JP No. 1-265511A), a method of dissolving a solid organometallic compound in a solvent, adsorbing it onto a porous particulate adsorbent, placing the resulting material on the mesh in a vessel, and then flowing upward from below the vessel (see JP No. 9-40489A), and a method of placing a particulate solid organometallic compound on the mesh in a vessel, and then flowing from below the vessel upward (JP No. 10-223540A).

On the other hand, a recent vapor phase growth reaction vessel has been larger to use a large amount of solid organometallic compounds, and thus the enlargement of a vessel used for supplying the solid organometallic compounds or the like is conducted.

A small amount of the organometallic compound which is supplied increases the amount of a solid organometallic compound remaining in a vessel, and thus decreases productivity. Therefore, an apparatus of supplying an organometallic compound is desired that can supply a solid organometallic compound at a more stable concentration at room temperature and make the amount of the organometallic compound which is supplied (the usage degree) higher than the conventional method or apparatus.

### SUMMARY OF THE INVENTION

An object of the present invention is to provide an apparatus of supplying an organometallic compound that can supply a solid organometallic compound at a more stable concentration at room temperature and make the usage degree of the solid organometallic compound higher.

The present inventors have diligently studied an apparatus of supplying a solid organometallic compound and found that a solid organometallic compound is effectively utilized by means of an apparatus of supplying an organometallic compound including a vessel having a supporter plate capable of maintaining an organometallic compound supported on an inert support in the lower part of the vessel with passing a carrier gas therethrough, a carrier gas inlet in the upper part of the vessel, and a carrier gas outlet downward of the supporter plate of being the bottom part of the vessel with passing the carrier gas through the organometallic compound supported on the inert support placed on the supporter plate from the above downward, having led to the present invention.

The present invention is an apparatus of supplying an organometallic compound comprising a vessel into which a solid organometallic compound at room temperature in placed and a carrier gas to sublimate the organometallic compound is supplied, a supporter plate capable of maintaining an organometallic compound supported on an inert support in the lower part of the vessel with passing a carrier gas therethrough, a carrier gas inlet in the upper part of the vessel, and a carrier gas outlet downward of the supporter plate of being the bottom part of the vessel, and the carrier gas is passed through the organometallic compound supported on the inert support from the above downward.

### BRIEF DESCRIPTION OF THE DRAWINGS

FIG. 1 is a sectional schematic diagram of a vessel in which a liquid organometallic compound is charged;

FIG. 2 is a sectional schematic diagram of a vessel in which a solid organometallic compound is charged;

FIG. 3 is a sectional schematic diagram of a vessel in which a solid organometallic compound supported on a conventional inert support is charged;

FIG. 4 is a sectional schematic diagram of one example of the vessel in which a solid organometallic compound supported on an inert support in the present invention;

FIG. 5 indicates one example of the schematic diagram of a supporter plate ((a) metal net shape supporter plate, (b) grating shapes supporter plate);

FIG. 6 indicates a graph illustrating the result in Example 1;

FIG. 7 indicates a graph illustrating the result in Comparative Example 1; and

FIG. 8 indicates a graph illustrating the result in Comparative Example 2.

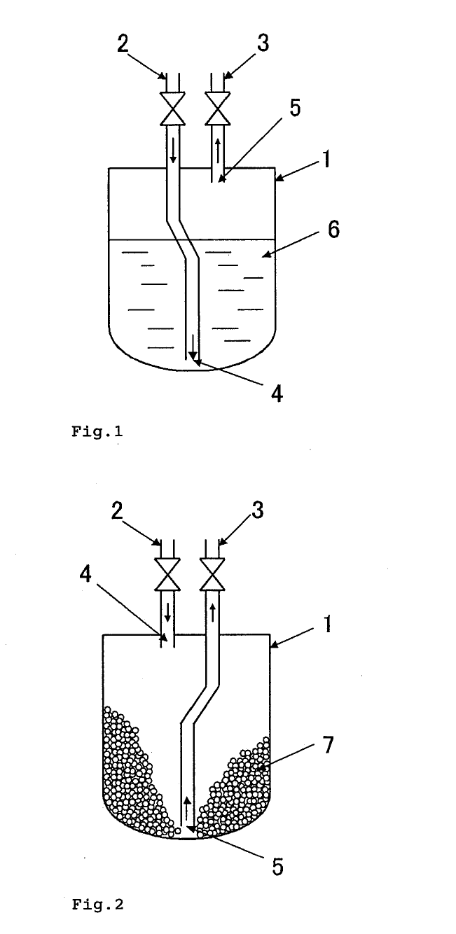

### DETAILED DESCRIPTION OF THE PREFERRED EMBODIMENTS

The solid organometallic compounds in the present invention include useful substances as raw materials of compound semiconductors by a vapor phase growth method and the like, for example, indium compounds such as trimethyl indium, dimethylchloroindium, cyclopentadienyl indium, trimethyl indium/trimethylarsine adducts and trimethyl indium/trimethylphosphine adducts, zinc compounds such as ethylzinc iodine, ethylcyclopentadienyl zinc and cyclopentadienyl zinc, aluminum compounds such as methyldichloroaluminum, gallium compounds such as methyldichlorogallium, dimethylchlorogallium and dimethylbromogallium, biscyclopentadienyl magnesium, and the like.

Additionally, the support supporting a solid organometallic compound that are used are not particularly limited so long as the supports are inactive to a solid organometallic compound and include ceramics such as alumina, silica, mullite, glassy carbon, graphite, potassium titanate, quartz, silicon nitride, arsenic nitride and silicon carbide, metals such as stainless, aluminum, nickel and tungsten, fluoride resin, glass, and the like.

The shapes of support that are used are not particularly limited and include a shape such as amorphous shape, spherical shape, fibrous shape, net shape, coil shape and cylindrical shape. The support surface preferably has fine tips and dips of from about 100 to about 2,000 μm in roughness rather than is flat, or has a number of pores (voids) in the support itself. The supports include alumina balls, Raschig rings, Heli Pack, Dixon packing, stainless sintered elements, glass wool, metal wool, and the like.

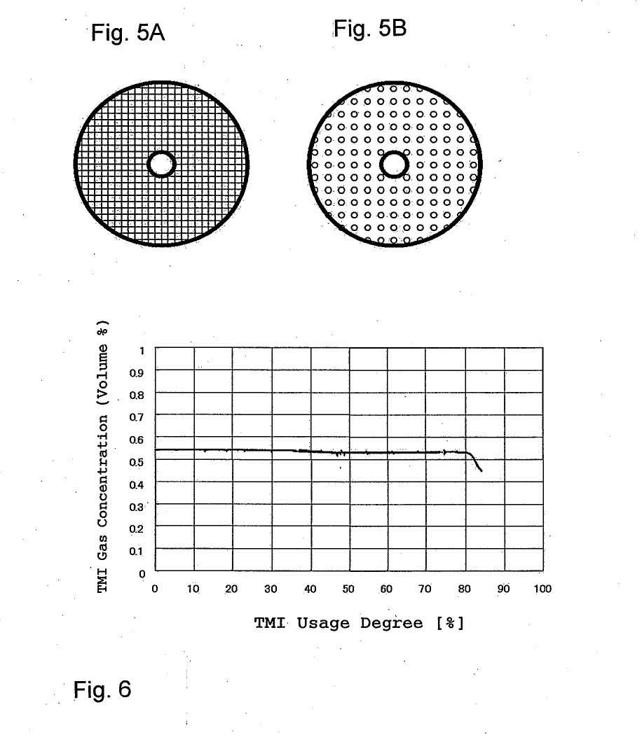

The supporter plates include metal net and grating (FIG. 5), and the size of the aperture is usually such a size that a support does not fall and usually is from about 1 to about 5 mm, preferably from about 1.5 to about 3 mm. The shape of the aperture is not particularly limited and includes polygonal shape, circular shape, ellipsoidal shape, and the like. The materials are not particularly limited so long as the materials are inactive to a solid organometallic compound, and can use glass, metals, ceramics and the like, preferably metals from the viewpoint of thermal conductivity, particularly preferably stainless.

The method of supporting a solid organometallic compound in an inert support can use a method conventionally performed. For example, the methods include a method of introducing a support and a solid organometallic metal compound into a rotating vessel in accordance with a predetermined weight ratio, heating the resulting material to melt the solid organometallic compound, and then gradually cooling the melt while rotation agitating, a method of introducing a support into a heat melted solid organometallic compound, withdrawing an excessive organometallic compound, and subsequently gradually cooling, and the like.

It is important to remove oxygen, moisture or other volatile impurities contained in the support before conducting supporting. If oxygen, moisture or the like is present on the support surface, a raw material may be deteriorated or contaminated. When an organometallic compound is used as a raw material for vapor phase growth or the like, the quality of a film obtained may be spoiled, or stable supply of a raw material may not be achieved sufficiently. For the avoidance of such, it is preferable that a support be vacuum deaerated in advance while heating in a temperature range in which the material is acceptable, and then the void portion be substituted by an inert gas such as nitrogen or argon.

The solid organometallic compound supported on a support is usually from about 10 to about 100 weight parts based on 100 weight parts of the support, preferably from about 30 to about 70 weight parts. If about 10 weight parts or less of a support is supported, the volume of the solid organometallic compound occupying the volume of vessel is small, so the vessel may be made to be larger than required in order to be enough amount of the solid organometallic compound and thus is not economical. In addition, when about 100 weight parts or more of a support is supported, the surface area of the solid organometallic compound per loaded volume does not become large as expected, so the advantage may not be sufficiently obtained.

FIG. 4 shows one embodiment of an apparatus of supplying an organometallic compound having a vessel containing a solid organometallic compound in the present invention. In the lower portion of a vessel 1 having a bent bottom part is disposed a supporter plate 9 capable of maintaining an organometallic compound supported on an inert support and passing a carrier gas therethrough. To the upper part of the vessel are connected a carrier gas inlet tube 2 and a carrier gas outlet tube 3. A carrier gas inlet 4 is an upper part of the vessel and is opened in the upper direction of the organometallic compound supported on an inert support; the carrier gas outlet tube 3 is passed through the inside of the vessel and a carrier gas outlet 5 is a bottom part and opened in the lower direction of the supporter plate.

In the figure the carrier gas outlet tube 3 is passed through the inside of the vessel, but is not limited thereto; if the outlet is opened in the lower direction in a bottom portion of the vessel, the inlet may be placed in the outside of the vessel.

A solid organometallic compound supported on an inert support is supplied in a desired amount into the vessel 1 from a supply inlet (not shown) and loaded on the supporter plate 9. In addition, as described above, a solid organometallic compound may be supported on an inert support within a vessel.

The carrier gas inlet tube 2 is connected to a carrier gas supply source, a flow rate control apparatus (not shown) and so forth; the carrier gas inlet 3 is connected to a gas concentration meter, a phase growth apparatus (not shown) and so forth, and the vessel 1 is placed in a thermostat bath and used.

A carrier gas such as hydrogen gas is supplied from the carrier gas inlet tube 2 in a predetermined flow rate and passed downward from the above of the vessel by way of the carrier gas inlet 4 via the space of the organometallic compound supported on the inert support, whereby the carrier gas containing the organometallic compound is supplied to the vapor phase growth apparatus, or the like by way of the carrier gas outlet tube 3 from the carrier gas outlet 5.

FIG. 4 indicates a vessel 1 in which the bottom of the vessel 1 has a bent shape. However, it is of course possible to use a vessel having a flat bottom as well. Additionally, it is also possible to separate the carrier gas outlet 5 into at least a plurality of outlets in the bottom to comparatively stably collect a gas.

For the amount of loading of an organometallic compound supported on an inert support into a vessel, the top end position of the loaded compound should usually be lower than the carrier gas inlet; however, this is not the case where the carrier gas inlet is separated and the vessel has a structure in which a carrier gas can be uniformly introduced to the upper part of an organometallic compound supported on an inert support. For instance, like the case where a separated plate or a carrier gas inlet with a shower head shape is employed, when a carrier gas is uniformly separately supplied, the position of the carrier gas inlet and the top end position of an organometallic compound may have substantially the same level.

An apparatus of supplying an organometallic compound of the present invention is suitable for an apparatus for supplying a raw material for vapor phase growth or the like.

### EXAMPLES

An example of the present invention will be set forth hereinafter; however, the invention is not limited thereto.

### Example 1

As in the vessel in FIG. 4, into a vessel having a bent bottom and a volume of about 1,000 cm³ (inner diameter: 110 mm, depth: 120 mm, a supporter plate located 26 mm above the lowest bottom part (size of the aperture: 110 mm wire gauge)) were loaded 435 g of aluminum globes having an average particle diameter (diameter) of 4.5 mm as an inert support and 300 g of trimethyl indium (hereinafter, referred to as TMI). The temperature of the vessel was increased to a temperature of about 110° C. that is higher than the melting point of TMI to melt TMI, and then the temperature of the resulting material was gradually cooled to room temperature with rotation agitation to support TMI on alumina.

Into a vessel into which TMI supported on the aluminum globes was loaded was flowed hydrogen gas as a carrier gas from a hydrogen cylinder at a substantially constant flow rate of about 900 cm³/min (f low rate per area of loaded part of the vessel in terms of atmospheric pressure: about 9.5 cm³/cm²·min). Hydrogen gas was supplied from an inlet tube 2 so as to pass from the above downward within the loaded TMI, and taken out of an outlet tube 3. The vessel was placed in a thermostat bath and kept at 25° C. The pressure within the vessel was set at 40 kPaA.

The TMI concentration in the hydrogen gas from the vessel was determined by means of an Epison densitometer (available from Thomas Swan Scientific Instrument Ltd.) as a gas densitometer.

The TMI concentration was periodically measured to evaluate the usage degree (%) of the TMI from the hydrogen gas flow rate and the TMI concentration. A result is shown in FIG. 6.

The concentration of the TMI was stable until the usage degree became about 80% and then was decreased.

### Comparative Example 1

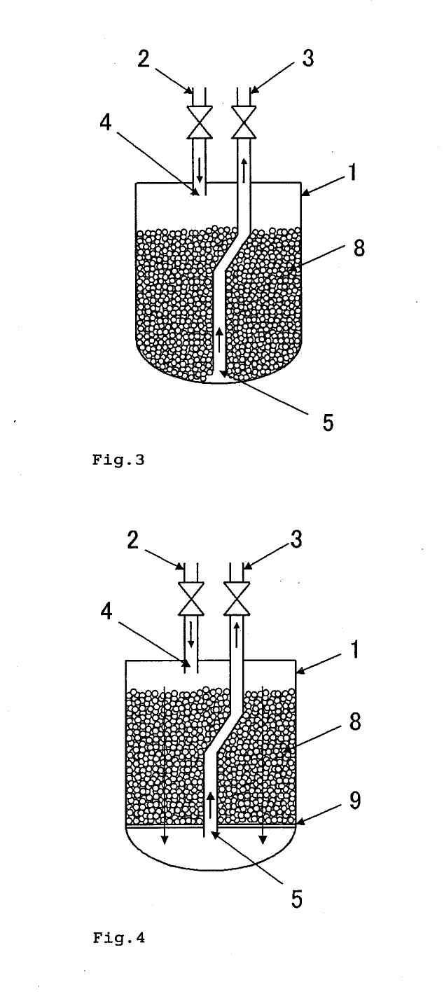

As in the vessel indicated in FIG. 3, in a vessel as in Example 1 except that the vessel uses no supporter plate, TMI was supported on alumina as in Example 1.

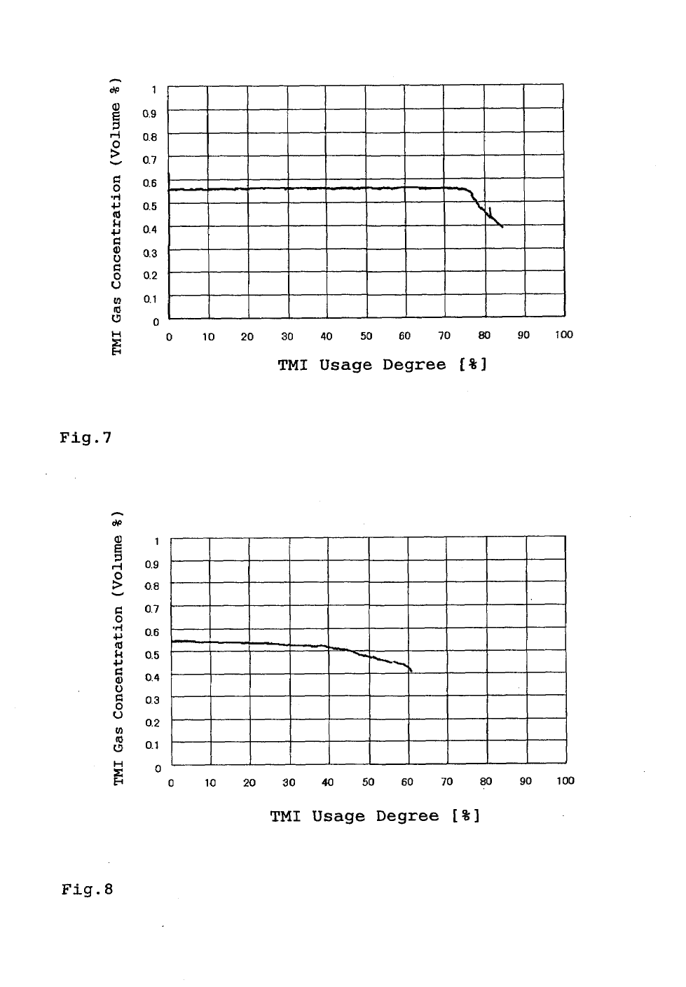

The usage degree (%) of the TMI was evaluated as in Example 1. The result is shown in FIG. 7.

The concentration of the TMI was stable until the usage degree became about 75% and then was decreased.

### Comparative Example 2

A procedure was carried out as in Example 1 except that hydrogen gas was supplied from an inlet tube 3 so as to pass from the below upward within the loaded TMI, contrary to Example 1, and taken out of an outlet tube 2.

The concentration of the TMI was decreased when the usage degree became about 30% and then was gradually decreased.

Use of a supplying apparatus of the present invention can supply a solid organometallic compound at a more stable concentration at room temperature and make the usage degree of the solid organometallic compound higher.

What is claimed is:

1. An apparatus of supplying an organometallic compound comprising a vessel into which a solid organometallic compound at room temperature is placed and a carrier gas to sublimate the organometallic compound is supported,
a supporter plate capable of maintaining an organometallic compound supported on an inert support in the lower part of the vessel with passing a carrier gas therethrough,
a carrier gas inlet in the upper part of the vessel, and a carrier gas outlet downward of the supporter plate of being the bottom part of the vessel are disposed, and wherein
the carrier gas is passed through the organometallic compound supported on the inert support loaded on the supporter plate from the above downward.

2. The apparatus of supplying an organometallic compound of claim 1, wherein
the supporter plate is a stainless wire gauze having an aperture size of from about 1 to about 5 mm.

3. The apparatus of supplying an organometallic compound of claim 1, wherein
the organometallic compound is trimethyl indium.
